(19) United States
(12) Patent Application Publication
(10) Pub. No.: US 2003/0141566 A1
(43) Pub. Date: Jul. 31, 2003

(54) Method of simultaneously manufacturing a metal oxide semiconductor device and a bipolar device

(75) Inventors: John C. Desko, Wescosville, PA (US); Chung-Ming Hsieh, Wyomissing, PA (US); Bailey Jones, Mohnton, PA (US); Thomas J. Krutsick, Fleetwood, PA (US); Brian E. Thompson, Sinking Spring, PA (US); Steve Wallace, Fleetwood, PA (US)

Correspondence Address: HITT GAINES P.C., P.O. BOX 832570, RICHARDSON, TX, 75083, US

(73) Assignee: Agere Systems Guardian Corp., Orlando, FL

(21) Appl. No.: 10/057,139

(22) Filed: Jan. 25, 2002

(51) Int. Cl. H01L 29/00

(52) U.S. Cl. 257/500

(57) ABSTRACT

The present invention provides a method of manufacturing a semiconductor device. The method may include forming first and second adjacent tubs in an epitaxial layer, and simultaneously forming a base region in the first tub and lightly doped drain (LDD) regions in the second tub adjacent a first gate located over the second tub. The method may also include simultaneously forming a base contact region and a source/drain contact region.

### TECHNICAL FIELD OF THE INVENTION

The present invention is directed, in general, to a method of manufacturing a semiconductor device and more specifically to a method to simultaneously form lightly doped drains (LDDS) of a metal oxide semiconductor (MOS) device and a base region of a bipolar device.

### BACKGROUND OF THE INVENTION

Integrated circuits are well known and are extensively used in various present day technological devices and systems, such as sophisticated telecommunications and computer systems of all types. As the use of integrated circuits continues to grow, the demand for more inexpensive and improved integrated circuits also continues to rise. Thus, presently, the emphasis in the semiconductor manufacturing industry is to provide higher density, faster devices at a competitive price.

Advancements in semiconductor technology have continued as the uses for integrated circuits has grown. For example, bipolar technology has been used extensively through the years for applications requiring high speed, high current drive, and low noise, and has successfully been incorporated into metal oxide semiconductor (MOS) manufacturing processes, such as those used to manufacture complementary MOS (CMOS) devices.

An integrated circuit having bipolar devices incorporated therein is especially desirable. Thus, recently emerging bipolar CMOS (BiCMOS) technologies combine bipolar devices with the traditional CMOS technologies, providing an integrated circuit that yields the desired high speed/high current capabilities of the bipolar devices, as well as the equally desired lower power usage of the CMOS devices. BiCMOS can operate at either ECL (emitter-coupled-logic) or TTL (transistor-transistor-logic) levels, and thus, is ideal for mixed-signal devices.

However, while bipolar devices are currently able to provide the high speed/high current capabilities presently desired, bipolar devices are more expensive to manufacture than traditional MOS devices. In many instances it may require an additional 6 to 8 masking steps to manufacture a bipolar device, as compared to a traditional MOS device. While lithography has been improved over the years, becoming less time consuming and inexpensive, it still comprises a substantial portion of the manufacturing expenses associated with producing integrated circuit devices. Typically, in the BiCMOS manufacturing process, the CMOS devices are completed before proceeding to build the bipolar devices. This modular approach adds process complexity which translates to higher manufacturing cost.

Accordingly, what is needed in the art is a method of manufacturing a BiCMOS device which provides desired high speed/high current capabilities, as well as the equally desired low power usage generally desired, however, that is much easier and less expensive to manufacture than the prior art BiCMOS devices.

### SUMMARY OF THE INVENTION

To address the above-discussed deficiencies of the prior art, the present invention provides a method of manufacturing a semiconductor device. In one embodiment the method includes forming first and second adjacent tubs in an epitaxial layer, and simultaneously forming a base region in the first tub and lightly doped drain (LDD) regions in the second tub adjacent a first gate located over the second tub.

In another embodiment, a method of manufacturing a bipolar metal oxide semiconductor device is presented. In this particular embodiment, the method includes forming first and second adjacent tubs in an epitaxial layer, constructing a metal oxide semiconductor transistor gate over the second tub, simultaneously forming a base region in the first tub and lightly doped drain (LDD) regions in the second tub adjacent the metal oxide semiconductor transistor gate, constructing a bipolar transistor emitter on the base region, and simultaneously forming extrinsic base contacts in the first tub and source/drain regions in the second tub.

In yet another embodiment, a method of manufacturing an integrated circuit is presented. In this particular embodiment, the method includes forming a plurality of first and second adjacent tubs in an epitaxial layer, constructing metal oxide semiconductor transistor gates over each of the second tubs, simultaneously forming base regions in each of the first tubs and lightly doped drain (LDD) regions in each of the second tubs adjacent each of the metal oxide semiconductor transistor gates, constructing bipolar transistor emitters on each of the base regions, and simultaneously forming extrinsic base contacts in each of the first tubs and source/drain regions in each of the second tubs.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

The invention is best understood from the following detailed description when read with the accompanying FIGUREs. It is emphasized that in accordance with the standard practice in the semiconductor industry, various features are not drawn to scale. In fact, the dimensions of the various features may be arbitrarily increased or reduced for clarity of discussion.

FIG. 1 illustrates one embodiment of a bipolar/metal oxide semiconductor device constructed in accordance with the principles of the present invention;

FIG. 2 illustrates a partially completed bipolar/metal oxide semiconductor device, which includes a partially completed metal oxide semiconductor transistor;

FIG. 3 illustrates the partially completed bipolar/metal oxide semiconductor device illustrated in FIG. 2, after simultaneously forming an intrinsic base region and lightly doped drain (LDD) regions;

FIG. 4 illustrates the partially completed bipolar/metal oxide semiconductor device illustrated in FIG. 3, including a dielectric layer deposited over the partially completed metal oxide semiconductor transistor and the intrinsic base region and an amorphous silicon layer formed over the dielectric layer;

FIG. 5 illustrates the partially completed bipolar/metal oxide semiconductor device illustrated in FIG. 4, after patterning an opening;

FIG. 6 illustrates the partially completed bipolar/metal oxide semiconductor device illustrated in FIG. 5, after conventionally depositing an emitter layer to fill the opening;

FIG. 7 illustrates the partially completed bipolar/metal oxide semiconductor device illustrated in FIG. 6, after deposition of a photo resist layer;

FIG. 8 illustrates the partially completed bipolar/metal oxide semiconductor device illustrated in FIG. 7, after forming an emitter;

FIG. 9 illustrates the partially completed bipolar/metal oxide semiconductor device illustrated in FIG. 8, after adding a conventionally deposited oxide layer;

FIG. 10 illustrates the partially completed bipolar/metal oxide semiconductor device illustrated in FIG. 9, after a conventional anisotropic etch is conducted to form oxide sidewall spacers on either side of both the gate and the emitter;

FIG. 11 illustrates the partially completed bipolar/metal oxide semiconductor device illustrated in FIG. 10, after implantation of an extrinsic base and source/drain regions to form the bipolar transistor and the metal oxide semiconductor transistor; and

FIG. 12 illustrates a sectional view of an integrated circuit (IC) device incorporating the completed bipolar/metal oxide semiconductor device 100 illustrated in FIG. 1.

### DETAILED DESCRIPTION

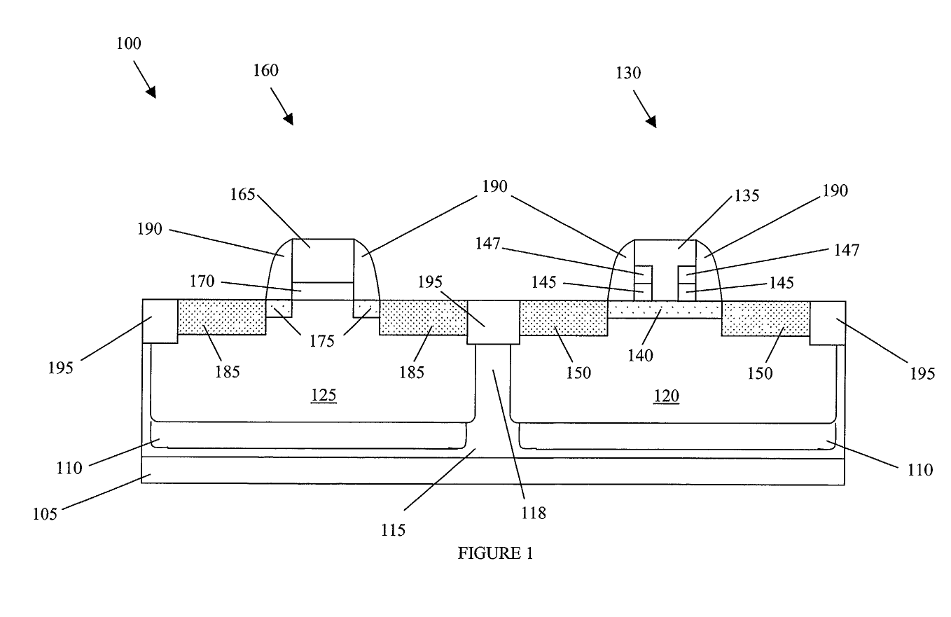

Referring initially to FIG. 1, illustrated is one embodiment of a bipolar/metal oxide semiconductor device, generally designated 100, constructed in accordance with the principles of the present invention. In the embodiment illustrated in FIG. 1, the bipolar/metal oxide semiconductor device 100 includes a bipolar transistor 130 and a metal oxide semiconductor transistor 160. Both the bipolar transistor 130 and the metal oxide semiconductor transistor 160 are located over a semiconductor wafer 105. The bipolar transistor 130 and the metal oxide transistor 160 are preferably formed over buried layers 110 formed in an epitaxial layer 115 deposited on the semiconductor wafer 105. However, it should be understood that these devices may be partially or fully formed in the semiconductor wafer 105 itself or in any layer located over the semiconductor wafer 105.

Located within the epitaxial layer 115 and over the buried layers 110 are first and second adjacent tubs, 120 and 125. As illustrated in FIG. 1, the first tub 120 serves as a collector for the bipolar transistor 130. It should be understood that the types of dopants used to form the collector are well known to those skilled in the pertinent art. Additionally, one who is skilled in this art is also familiar with the dopant profiles required to form either a PNP, NPN or other dopant profile for a bipolar transistor. In an exemplary embodiment, the first and second tubs, 120, 125, may be doped with a first dopant to a concentration ranging from about 5E15 to 1E17 atoms/cm³ in the tub and from 5E18 to 5E19 atoms/cm³ in the buried layers 110. In alternative embodiments, tubs for a metal oxide semiconductor device may be different and may also include threshold adjustment implants. Other concentrations are also within the scope of the present invention.

The bipolar transistor 130 includes an intrinsic base region 140 located within the first tub 120. The intrinsic base region 140, in this particular embodiment, is doped with a second dopant that is different from the first dopant used to form the first tub 120. In an exemplary embodiment, the intrinsic base region 140 may be doped to a concentration ranging from about 5E17 atoms/cm³ to about 5E18 atoms/cm³ for a peak concentration of base implants. Extrinsic base regions 150 contact the intrinsic base region 140 with the first tub 120. In an exemplary embodiment, the extrinsic base regions 150 are doped with the second dopant to a dopant concentration ranging from about 5E19 atoms/cm³ to about 2E20 atoms/cm³.

Also illustrated in FIG. 1 as a part of the bipolar transistor 130, is an emitter 135 located over the intrinsic base region 140 and on the epitaxial layer 115 and deposited amorphous silicon 147. The deposited amorphous silicon 147 is over a deposited dielectric layer 145. In an exemplary embodiment, the emitter 135 is preferably doped with the appropriate dopant to a concentration ranging from about 1E20 atoms/cm³ to about 5E21 atoms/cm³.

The bipolar transistor 130 may be, in one embodiment, an NPN bipolar transistor, wherein the first dopant is an N-type dopant and the second dopant is a P-type dopant. In an alternative embodiment, the dopant types could be reversed, to provide a PNP bipolar transistor.

The metal oxide semiconductor transistor 160 includes a gate 165, such as a polysilicon or metal gate, that is located over a conventional gate oxide 170. The gate oxide 170 is preferably located on the epitaxial layer 115 over the second tub 125. As shown in FIG. 1, the gate 165, the gate oxide 170 and the emitter 135 may be located between conventionally formed oxide sidewall spacers 190.

Located adjacent to and on either side of the gate 165 and within the second tub 125, are lightly doped drain (LDD) regions 175 that are doped with the same type of dopant used to form the intrinsic base region 140 and which is a different dopant than that used to form the first and second tubs 120, 125. In an exemplary embodiment, the (LDD)regions 175 may be doped to a concentration ranging from about 5E17 atoms/cm³ to about 5E18 atoms/cm³. Contacting the (LDD)regions 175 and located within the second tub 125, are source/drain contact regions 185 that in an exemplary embodiment, may function as source/drain contact enhancements for the (LDD)regions 175.

The bipolar transistor 130 and the metal oxide semiconductor transistor 160 illustrated in FIG. 1 are isolated by a recessed oxide 195. In an exemplary embodiment, the bipolar transistor 130 and the metal oxide semiconductor transistor 160 are further isolated or separated by an intervening region 118 with a reverse type dopant from the tubs. For example, n-type tubs are separated by p-doped region, and p-type tubs are separated by n-doped region. However, other methods, such as deep trench isolation of the devices, are possible to isolate the tubs of bipolar transistors from other transistors including, for instance, the metal oxide semiconductor transistor 160 as shown in FIG. 1.

In one embodiment, the metal oxide semiconductor transistor 160 may be a PMOS transistor, wherein the LDD regions 175 and the source/drain contact regions 185 are doped with a P-type dopant and the second tub 125 is doped with an N-type dopant. In such embodiments, the intrinsic base region 140 and the base contact region 150 are also doped with the P-type dopant, while the first tub 120 associated with the bipolar transistor is doped with the N-type dopant to form a NPN bipolar transistor. Alternatively, these dopant schemes may be reversed for both devices to provide an NMOS transistor and an PNP bipolar transistor. In one embodiment, NMOS and PNP bipolar transistors may be formed on a semiconductor wafer with PMOS and NPN bipolar transistors. Additionally, while FIG. 1 illustrates only one pair of devices, it should be understood that this design is expandable to include any desired number of pairs of bipolar transistors 130 and metal oxide semiconductor transistors 160. Furthermore, alternative embodiments may have any number of bipolar transistors 130 adjacent to each other and/or adjacent to any number of metal oxide semiconductor transistors 160.

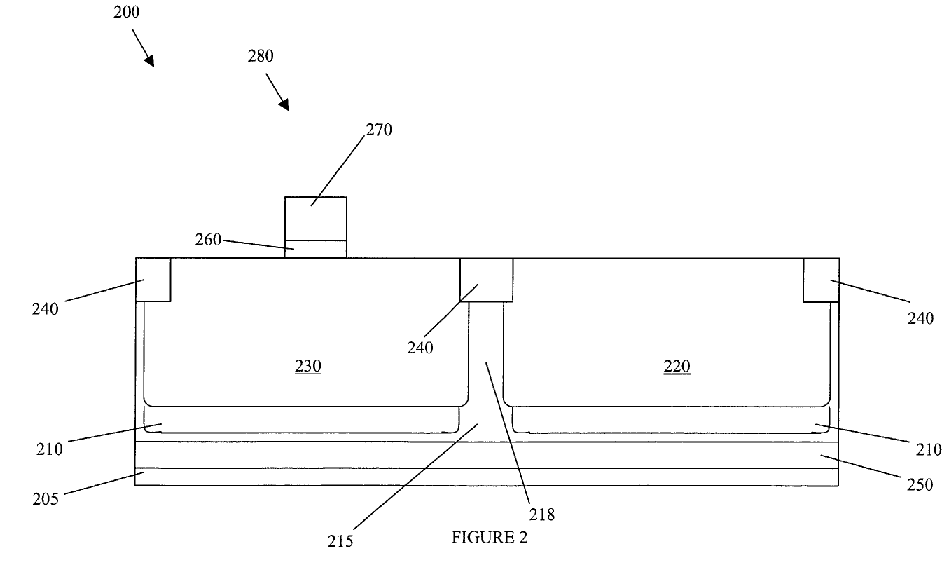

Turning now to FIGS. 2-13, illustrated are detailed steps illustrating how a bipolar/metal oxide semiconductor device illustrated in FIG. 1 might be manufactured. Illustrated in FIG. 2 is a partially completed bipolar/metal oxide semiconductor device 200, which includes a partially completed metal oxide semiconductor transistor 280 located over a semiconductor wafer 205. The partially completed metal oxide semiconductor transistor 280 includes a conventionally formed gate 270 located on a conventionally formed gate oxide 260. The gate oxide 260 is located over a second tub 230. The second tub 230 is formed over a buried layer 210 which is formed in an epitaxial layer 215 and is doped with the dopant schemes and concentrations discussed above.

Also illustrated in FIG. 2 and formed over the buried layer 210 and contained within the epitaxial layer 215, is a first tub 220, which will serve as a collector for a bipolar transistor. The first tub 220 and the second tub 230 are isolated by a conventionally formed recessed oxide 240. In an exemplary embodiment, the first tub 220 and the second tub 230 are further isolated by an intervening region 218 with a doping opposite that of the first tub 220 and the second tub 230, or alternatively isolated by a deep trench (not shown) extending below the buried layers. The first tub 220 and the second tub 230 are preferably similarly doped to a concentration ranging from about 5E15 atoms/cm³ to about 1E17 atoms/cm³. In certain embodiments, a low doped silicon layer 250 may be located under the epitaxial layer 215.

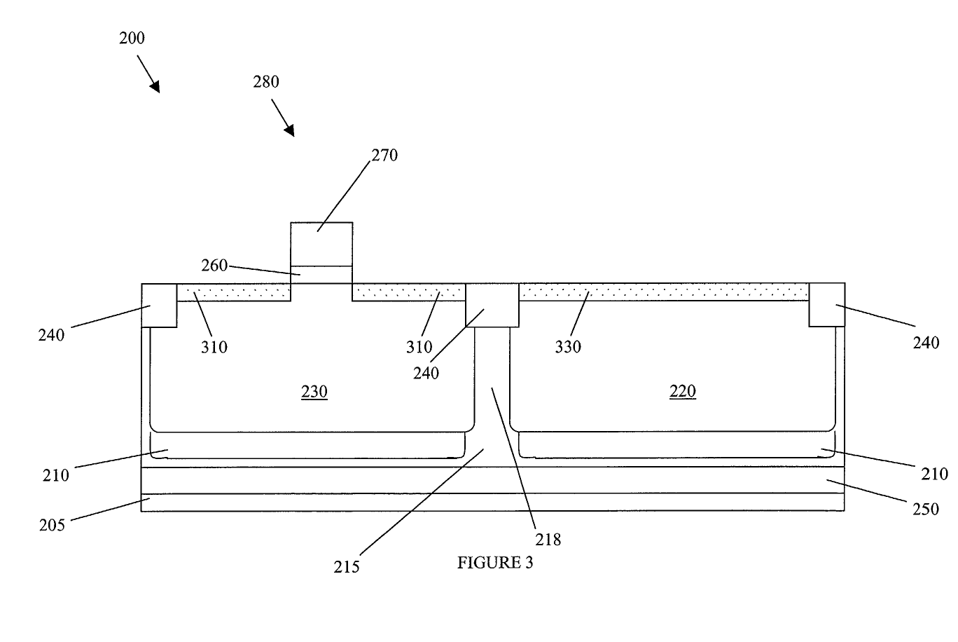

Turning now to FIG. 3, illustrated is the partially completed bipolar/metal oxide semiconductor device 200 illustrated in FIG. 2, after simultaneously forming a base region 330 in the first tub 220 and lightly doped drain (LDD) regions 310 in the second tub 230 adjacent the partially completed metal oxide semiconductor transistor 280. The lightly doped drain (LDD) regions 310 in the second tub 230 will serve as intrinsic source/drains for the metal oxide semiconductor transistor 160 of FIG. 1. Since, the base region 330 and the LDD regions 310 are formed at the same time, they can be doped substantially the same and have similar doping concentrations.

Forming the the lightly doped drain (LDD) regions 310 in the second tub 230 and the intrinsic base region 330 in the first tub 220 in the same step reduces the cost of manufacturing a bipolar/metal oxide semiconductor device because they are accomplished using the same mask, thereby reducing the number of masks required and reducing the number of steps needed to manufacture the device. The processes used to implant the LDD regions 310 and the intrinsic base region 330 may be done using conventional implantation processes and dopants.

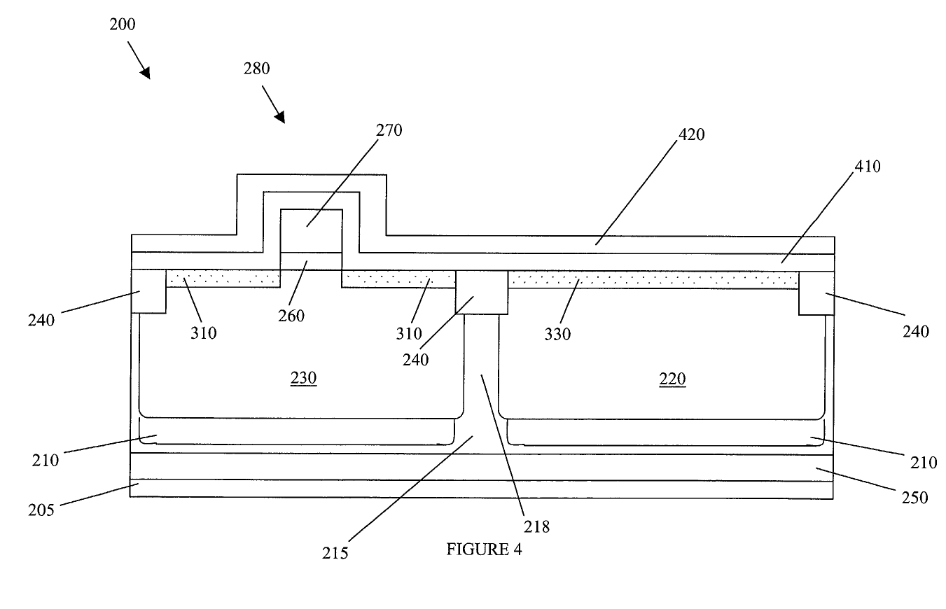

Turning now to FIGS. 4-9, illustrated are detailed steps illustrating how the emitter 135 of the bipolar transistor 130 illustrated in FIG. 1, may be manufactured. As shown in FIG. 4, a dielectric layer 410 is deposited over the gate 270 and the surface of the semiconductor wafer 205. A conventional chemical vapor deposition process using tetraethylorthosilicate gas may be used to deposit the dielectric layer 410. As further shown in FIG. 4, a conventionally deposited amorphous silicon layer 420 is formed over the dielectric layer 410.

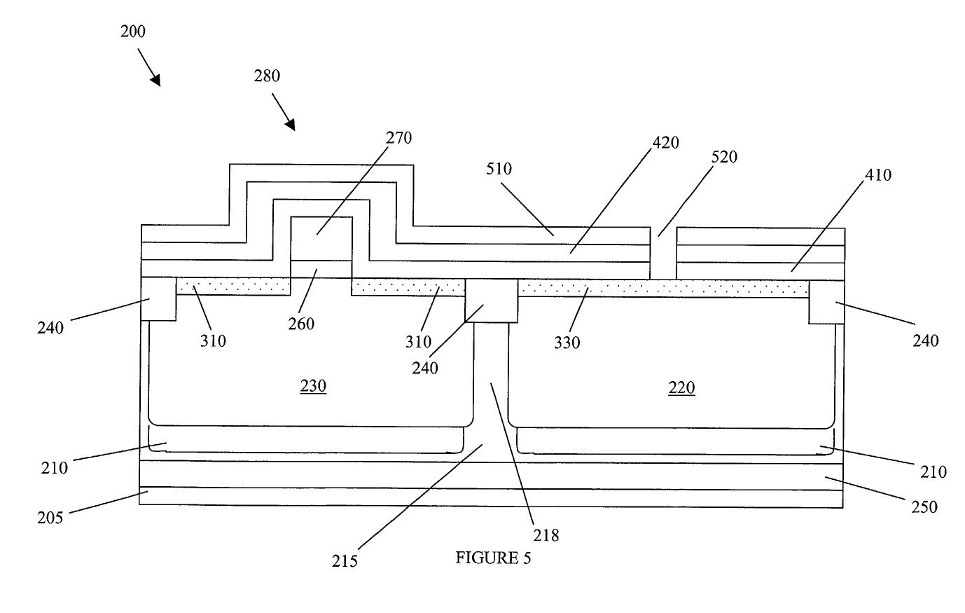

As shown in FIG. 5, a photoresist layer 510 is conventionally deposited and patterned after which a conventional etch is conducted to form an opening 520 through the amorphous silicon layer 420 and the dielectric layer 410 to contact the intrinsic base region 330. After formation of the opening 520, the photoresist layer 510 is conventionally removed.

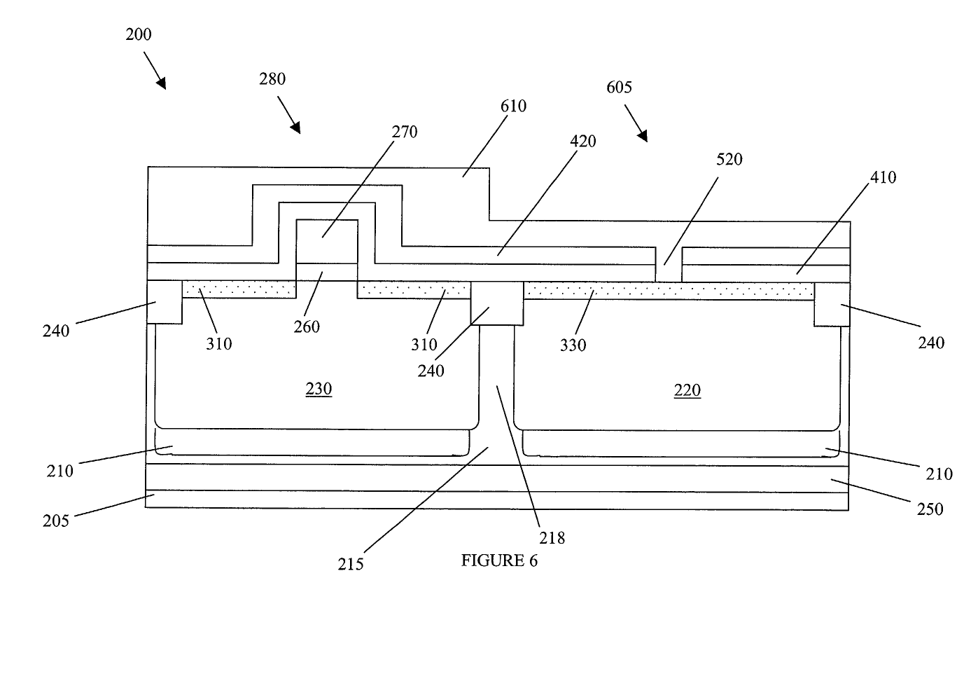

After removal of the photoresist layer 510, an emitter layer 610 is conventionally deposited to fill the opening 520, as shown in FIG. 6. In an exemplary embodiment, the emitter layer 610 may be comprised of doped polysilicon. If the partially completed bipolar transistor 605 is to be an NPN bipolar transistor, then the emitter layer 610 will be doped with an N-type dopant, while the base will be doped with P-type dopant and the tub will be doped with an N-type dopant. The doping schemes may be reversed to form an NMOS metal oxide semiconductor device and a PNP bipolar transistor.

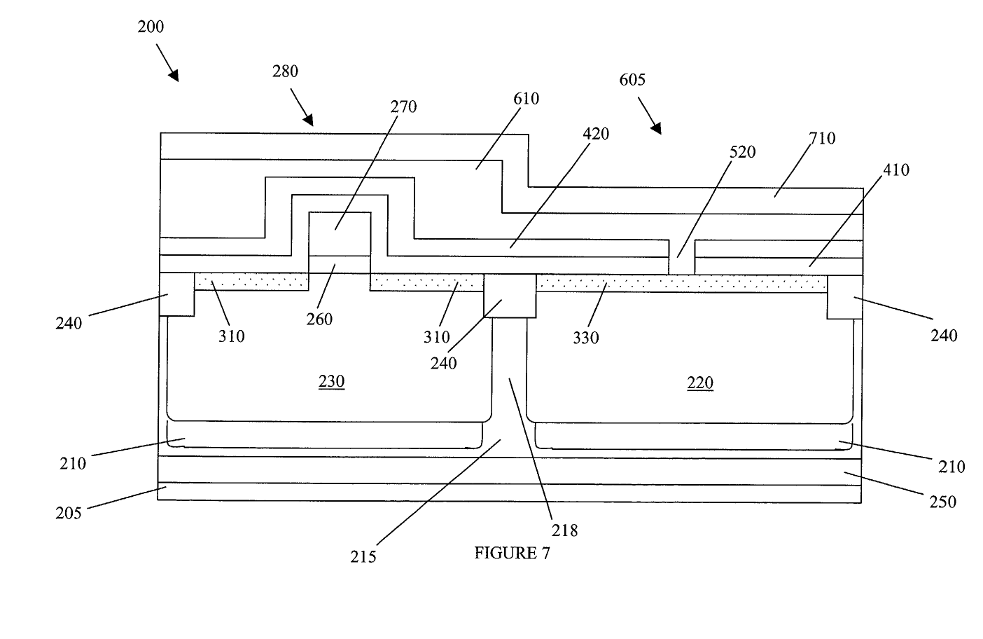

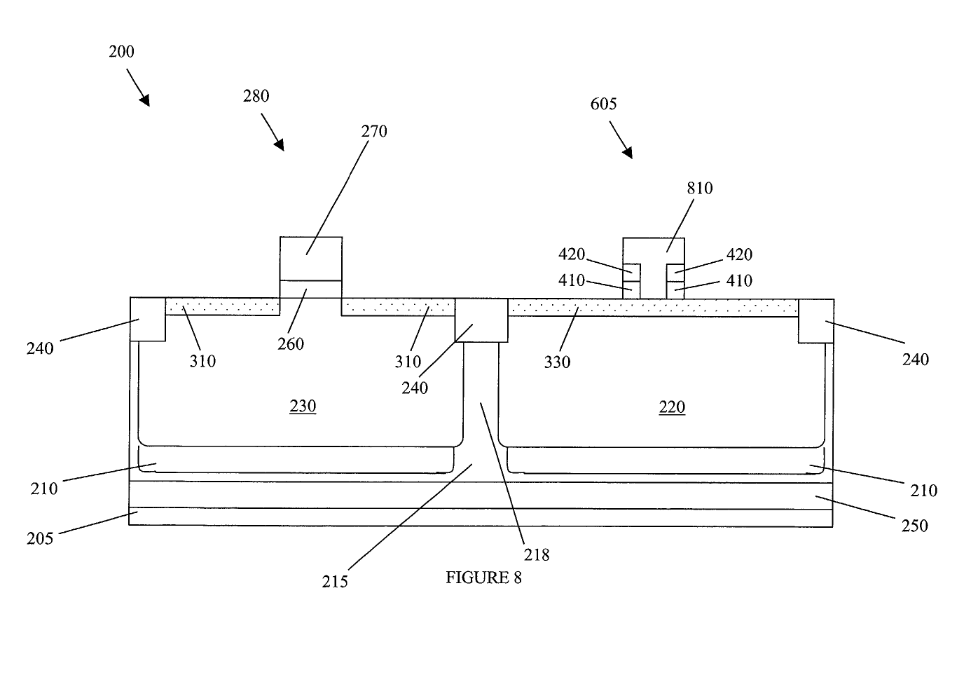

As illustrated in FIG. 7, a photoresist layer 710 is conventionally deposited over the emitter layer 610 and patterned and etched to form the emitter 810, as shown in FIG. 8.

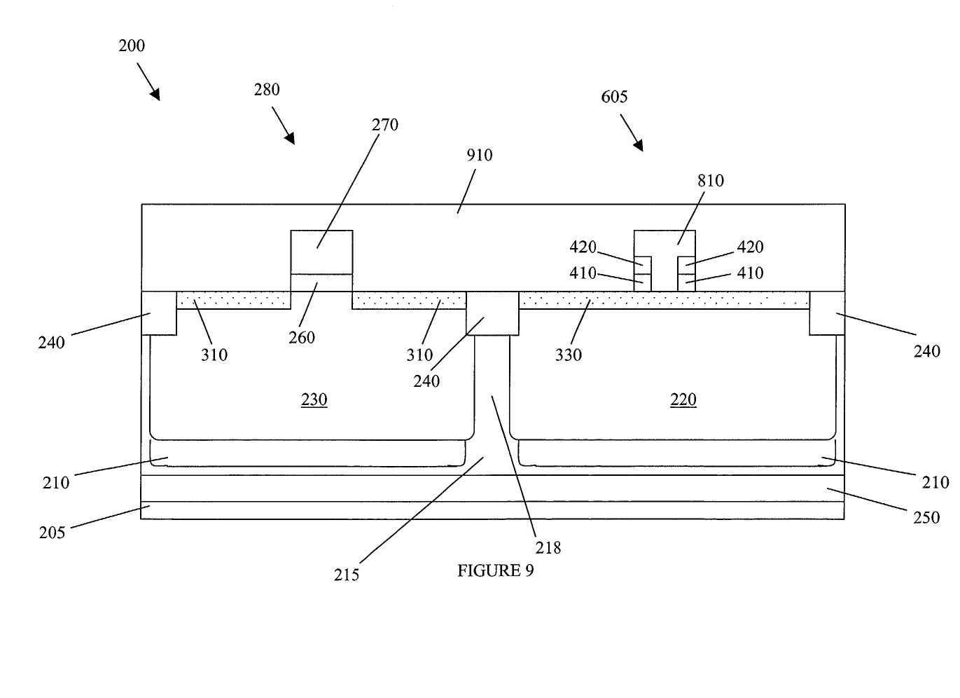

Turning now to FIG. 9, illustrated is the partially completed bipolar/metal oxide semiconductor device 200 illustrated in FIG. 8, after adding a conventionally deposited oxide layer 910 over the partially completed metal oxide semiconductor transistor 280 and the partially completed bipolar transistor 605.

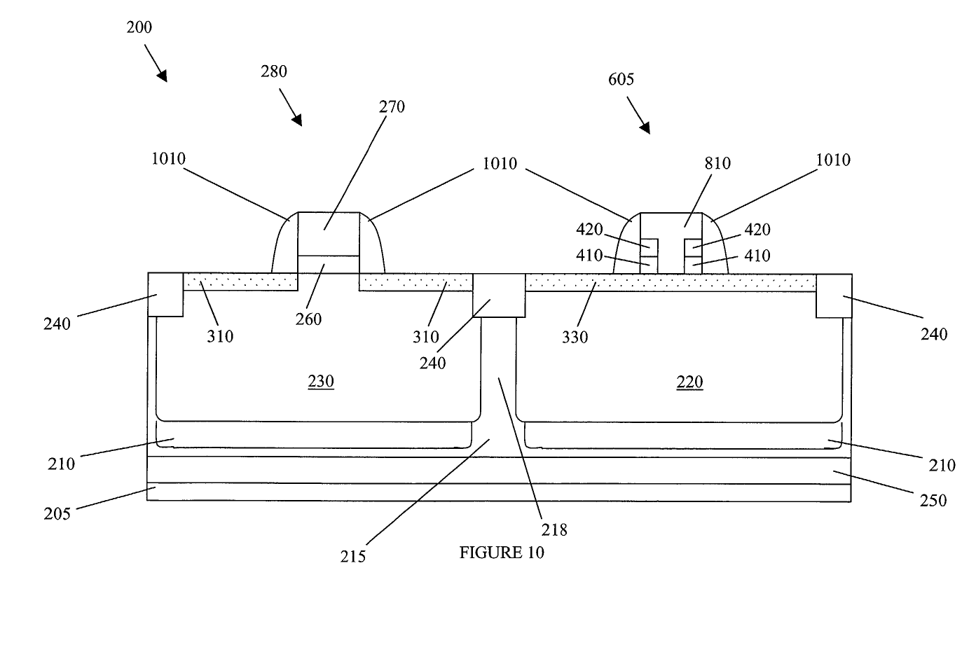

Turning now to FIG. 10, illustrated is the partially completed bipolar/metal oxide semiconductor device 200 illustrated in FIG. 9, after a conventional anisotropic etch is conducted to form oxide sidewall spacers 1010 on either side of both the gate 270 and the emitter 810.

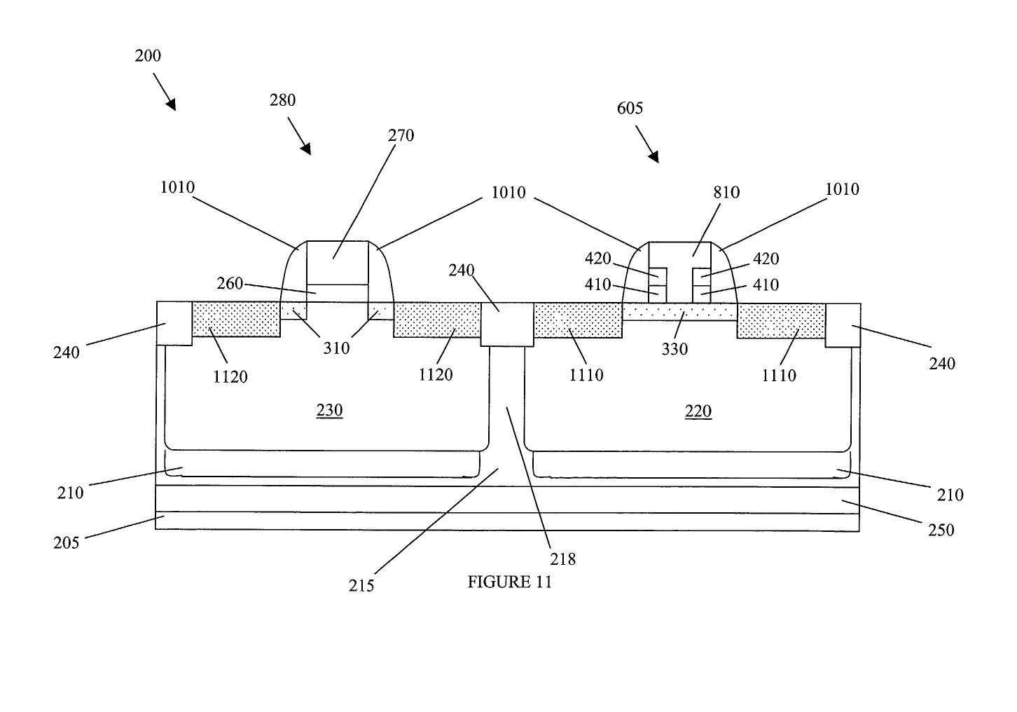

Turning now to FIG. 11, illustrated is a partially completed bipolar/metal oxide semiconductor device 200 illustrated in FIG. 10, after the simultaneous implantation of an extrinsic base 1110 and source/drain regions 1120 to form the bipolar transistor 130 and metal oxide semiconductor transistor 160 as shown in FIG. 1. The extrinsic base 1110 may serve as base contacts for the bipolar transistor 130 and the source/drain regions 1120 may function as source/drain contact enhancements for the metal oxide semiconductor transistor 160. The implantation may be conducted with conventional processes to implant the dopants to form the desired devices as discussed above.

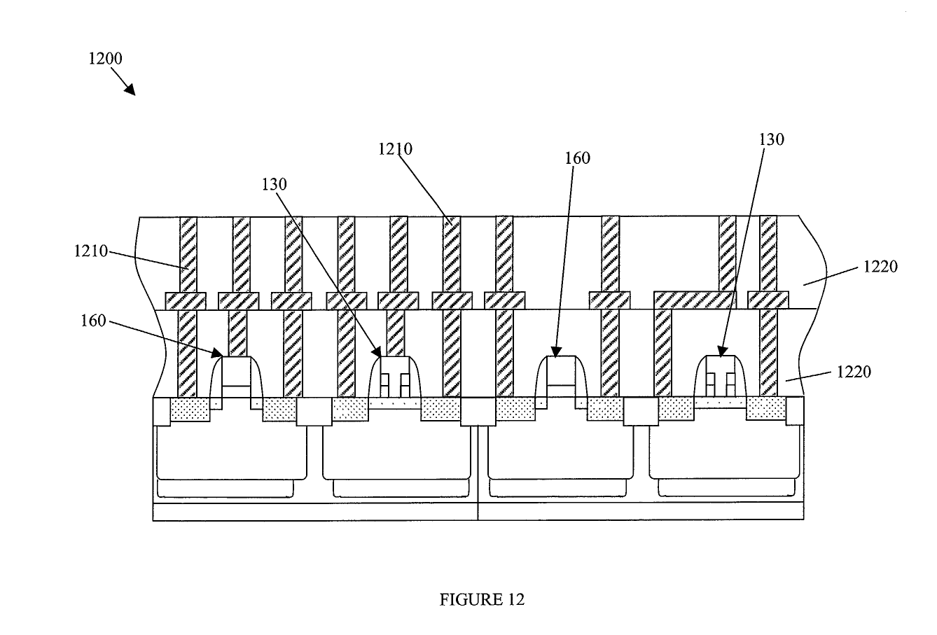

Referring now to FIG. 12, illustrated is a sectional view of an integrated circuit (IC) device 1200 incorporating the completed bipolar/metal oxide semiconductor device 100 illustrated in FIG. 1. The IC device 1200 may include active devices, such as transistors used to form CMOS devices, bipolar devices, or other types of active devices. The IC device 1200 may further include passive devices, such as inductors or resistors, or it may also include optical devices or optoelectronic devices. Those skilled in the art are familiar with these various types of devices and their manufacture. In the particular embodiment illustrated in FIG. 12, the IC device 1200 includes the bipolar transistor 130 and the metal oxide semiconductor transistor 160 as discussed above. Interconnect structures 1210, are located within a dielectric layer 1220 to interconnect these devices to form an operative integrated circuit.

Although the present invention has been described in detail, those skilled in the art should understand that they can make various changes, substitutions and alterations herein without departing from the spirit and scope of the invention in its broadest form.

What is claimed is:

1. A method of manufacturing a semiconductor device, comprising:
forming first and second adjacent tubs in a semiconductor substrate; and
simultaneously forming a base region in the first tub and lightly doped drain (LDD) regions in the second tub adjacent a first gate located over the second tub.

2. The method as recited in claim 1 further including constructing an emitter on the base region.

3. The method as recited in claim 2 wherein constructing an emitter includes patterning a dielectric layer over the first tub to form a patterned dielectric layer.

4. The method as recited in claim 3 wherein constructing the emitter includes depositing and patterning a conductive material over the patterned dielectric layer.

5. The method as recited in claim 1 further including constructing an emitter on the base region and simultaneously forming extrinsic base contacts in the first tub and source/drain regions in the second tub.

6. The method as recited in claim 1 wherein forming the first and second tubs includes doping the first and second tubs with a same type of dopant and doping the first tub to form a collector.

7. The method as recited in claim 1 further including forming a bipolar transistor gate on the base region and a metal oxide semiconductor transistor gate over the second tub.

8. A method of manufacturing a bipolar/metal oxide semiconductor device, comprising:
forming first and second adjacent tubs in a semiconductor substrate;
constructing a metal oxide semiconductor transistor gate over the second tub;
simultaneously forming a base region in the first tub and lightly doped drain (LDD) regions in the second tub adjacent the metal oxide semiconductor transistor gate;
constructing a bipolar transistor emitter on the base region; and
simultaneously forming extrinsic base contacts in the first tub and source/drain regions in the second tub.

9. The method as recited in claim 8 wherein constructing the bipolar transistor emitter includes patterning a dielectric layer over the first tub to form a patterned dielectric layer.

10. The method as recited in claim 9 wherein patterning the dielectric layer includes patterning a silicon dioxide over the first tub to form a patterned silicon dioxide layer.

11. The method as recited in claim 8 wherein constructing the bipolar transistor emitter includes depositing and patterning a conductive material over the patterned dielectric layer.

12. The method as recited in claim 11 wherein depositing includes depositing and patterning polysilicon over the patterned silicon dioxide.

13. The method as recited in claim 8 wherein forming the first and second tubs includes doping the first and second tubs with a same type of dopant and doping the first tub to form a collector.

14. A method of manufacturing an integrated circuit, comprising:
forming a plurality of first and second adjacent tubs in a semiconductor substrate;
constructing metal oxide semiconductor transistor gates over each of the second tubs;
simultaneously forming base regions in each of the first tubs and lightly doped drain (LDD) regions in each of the second tubs adjacent each of the metal oxide semiconductor transistor gates;
constructing bipolar transistor emitters on each of the base regions; and
simultaneously forming extrinsic base contacts in each of the first tubs and source/drain regions in each of the second tubs.

15. The method as recited in claim 14 wherein constructing the bipolar transistor emitters includes patterning a dielectric layer over to form patterned dielectric layer over each of the first tubs.

16. The method as recited in claim 15 wherein patterning the dielectric layer includes patterning a silicon dioxide over each of the first tubs to form a patterned silicon dioxide layer.

17. The method as recited in claim 15 wherein constructing the bipolar transistor emitters includes depositing and patterning a conductive material over each of the patterned dielectric layers.

18. The method as recited in claim 17 wherein depositing includes depositing and patterning polysilicon.

19. The method as recited in claim 14 wherein forming the plurality of first and second tubs includes doping the first and second tubs with a same type of dopant and doping the first tub to form a collector.

20. The method as recited in claim 14 further including forming a multi-level interconnect system that interconnect the metal oxide transistor gates and the bipolar transistor gates to form an operative integrated circuit.

21. A bipolar/metal oxide semiconductor device, comprising:
a metal oxide gate located on a semiconductor substrate and over a first tub having intrinsic and extrinsic source/drain regions formed therein, the intrinsic source/drain region having a dopant concentration therein and the extrinsic source/drain regions having a dopant concentration therein greater than the dopant concentration of the intrinsic source/drain regions; and
a bipolar transistor located adjacent the first tub and over a second tub and including an emitter located over said substrate and an intrinsic base region located in the second tub, the intrinsic base region having a doping density substantially the same as the dopant concentration of the intrinsic source/drain regions.

22. The bipolar/metal oxide semiconductor device as recited in claim 21 wherein dopant concentrations of the intrinsic source/drain regions and the intrinsic base region range from about 5E17 atoms/cm³ to about 5E18 atoms/cm³.

23. The bipolar/metal oxide semiconductor device as recited in claim 21 further including extrinsic base regions adjacent the intrinsic base regions and wherein a dopant concentration of the extrinsic base regions range from about 5E19 atoms/cm³ to about 2E20 atoms/cm³.
